(19) United States
(12) Patent Application Publication
(10) Pub. No.: US 2024/0215293 A1
(43) Pub. Date: Jun. 27, 2024

(54) DISPLAY DEVICE AND METHOD OF MANUFACTURING THE SAME

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 18/391,719

(22) Filed: Dec. 21, 2023

(30) Foreign Application Priority Data
Dec. 23, 2022 (JP) 2022-206958

(51) Int. Cl. H10K 50/15; H10K 59/35; H10K 71/10

(52) U.S. Cl. CPC H10K 50/156; H10K 59/35; H10K 71/10

(57) ABSTRACT

According to one embodiment, a display device includes a first anode, a cathode opposing the first anode and a first organic layer located between the first anode and the cathode, and the first organic layer includes a first light emitting layer and a hole transport layer located between the first anode and the first light emitting layer, and an average particle diameter per unit area of a material which constitutes the first light emitting layer is smaller than an average particle diameter per unit area of a material which constitutes the hole transport layer.

### CROSS-REFERENCE TO RELATED APPLICATIONS

This application is based upon and claims the benefit of priority from Japanese Patent Application No. 2022-206958, filed Dec. 23, 2022, the entire contents of which are incorporated herein by reference.

### FIELD

Embodiments described herein relate generally to a display device and a method of manufacturing the display device.

### BACKGROUND

In recent years, display devices in which an organic light emitting diode (OLED) is applied as a display element have been put to practical use. Such a display device comprises an anode, a cathode opposing the anode and an organic layer located between the anode and the cathode. The organic layer includes functional layers such as a hole transport layer and an electron transport layer, in addition to a light emitting layer.

In such display devices, there is a demand to improve the light emission properties.

### BRIEF DESCRIPTION OF THE DRAWINGS

FIG. 1 is a perspective view showing a display device DSP according to an embodiment.

FIG. 2 is a diagram illustrating an example of layout of pixels PX in a display area DA shown in FIG. 1.

FIG. 3 is a diagram showing an example of the configuration of each pixel shown in FIG. 2.

FIG. 4 is a diagram illustrating an example of a method of manufacturing display elements 201, 202 and 203 shown in FIG. 3.

FIG. 5 is a diagram including micrographs showing a light emitting layer B-EML formed at a deposition rate of the embodiment.

FIG. 6 is a diagram including micrographs showing a light emitting layer B-EML formed at a deposition rate of a comparative example.

FIG. 7 is a diagram showing a modelled configuration of each layer of the organic layer OR1.

FIG. 8A is a diagram showing an example of a relationship between applied voltage and current density in the display element 201.

FIG. 8B is a diagram showing an example of a relationship between applied voltage and current density in the display element 202.

FIG. 8C is a diagram showing an example of a relationship between applied voltage and current density in the display element 203.

FIG. 8D is a diagram showing an efficiency in the display elements 201, 202 and 203.

FIG. 9A is a diagram showing a decay process of luminescence intensity over elapsed time in the display element 201.

FIG. 9B is a diagram showing a decay process of luminescence intensity over elapsed time in the display element 202.

FIG. 9C is a diagram showing a decay process of luminescence intensity over elapsed time in the display element 203.

FIG. 10 is a diagram showing the change in luminescence intensity over elapsed time in the display element 201.

FIG. 11 is a diagram showing the change in luminescence intensity over elapsed time in the display element 202.

FIG. 12 is a diagram showing the change in luminescence intensity over elapsed time in the display element 203.

### DETAILED DESCRIPTION

In general, according to one embodiment, a display device comprises a first anode, a cathode opposing the first anode and a first organic layer located between the first anode and the cathode, and the first organic layer includes a first light emitting layer and a hole transport layer located between the first anode and the first light emitting layer, and an average particle diameter per unit area of a material which constitutes the first light emitting layer is smaller than an average particle diameter per unit area of a material which constitutes the hole transport layer.

According to another embodiment, a method of manufacturing a display device, comprises forming a first anode, forming a first organic layer on the first anode and forming a cathode on the first organic layer, and the forming the first organic layer comprises forming a hole transport layer; and forming a first light emitting layer, and the hole transport layer is located between the first anode and the first light emitting layer, and at least one of the hole transport layer and the first light emitting layer is formed at a deposition rate of 0.12 nm per second or higher.

Embodiments will be described hereinafter with reference to the accompanying drawings.

Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and an overlapping detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as a first direction X, a direction along the Y axis is referred to as a second direction Y and a direction along the Z axis is referred to as a third direction Z. Viewing the elements in parallel with the third direction Z is referred to as plan view.

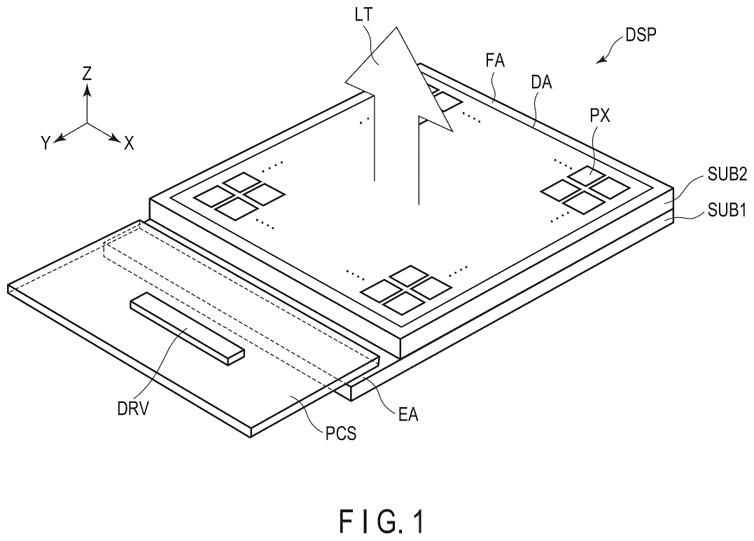

FIG. 1 is a perspective view showing a display device DSP according to an embodiment.

The display device DSP comprises substrates SUB1 and SUB2. The substrates SUB1 and SUB2 are each constituted by a glass substrate or a resin film as a base. The substrate SUB1 includes a display area DA which displays images and a peripheral area FA which surrounds the display area DA. The display area DA comprises a plurality of pixels PX arranged in a matrix along the first direction X and the second direction Y. The substrate SUB2 is overlaid on the display area DA. The peripheral area FA includes a terminal area EA for connecting a wiring board PCS and the like. The terminal area EA is located on an extending side of the substrate SUB1, which protrudes out further from the substrate SUB2.

The wiring board PCS contains a drive element DRV provided thereon, that outputs video signals and drive signals. The signals from the drive elements DRV are input to the pixels PX in the display area DA via the wiring board PCS. Each of the pixels PX emits light based on the video signals and various control signals. Emitted light LT from each pixel PX is transmitted through the substrate SUB2 and observed as an image.

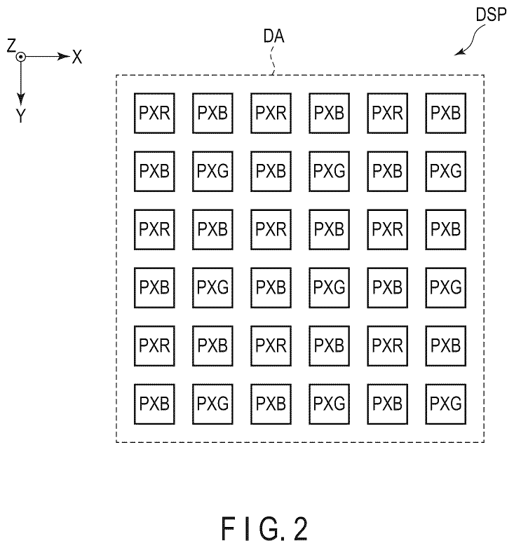

FIG. 2 is a diagram showing an example of layout of pixels PX in the display area DA shown in FIG. 1.

The display area DA includes, as the pixels PX, pixels PXB configured to emit blue light, pixels

PXG configured to emit green light and pixels PXR configured to emit red light. The pixels PXR and the pixels PXB are arranged alternately along the first direction X and the second direction Y. The pixels PXG and the pixels PXB are arranged alternately along the first direction X and the second direction Y.

The layout of the pixels PX is not limited to that of the example shown in the figure.

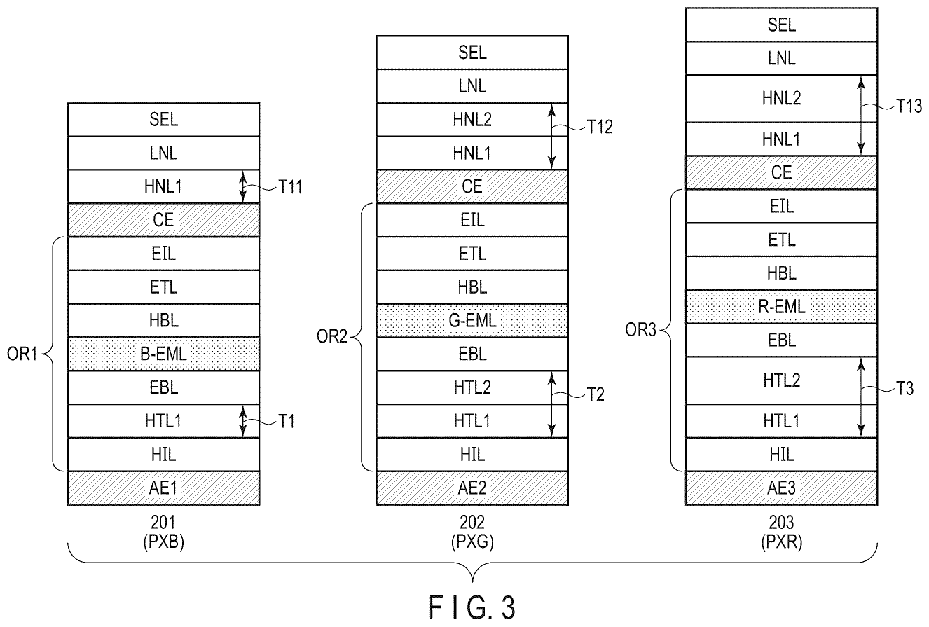

FIG. 3 is a diagram showing an example of the configuration of each of the pixels shown in FIG. 2.

The pixels PXB comprise a display element 201, the pixels PXG comprise a display element 202 and the pixels PXR comprise a display element 203. The display elements 201, 202 and 203 are organic light emitting diodes (OLEDs) as light emitting elements and they may as well be referred to as organic EL elements.

The display element 201 comprises an anode AE1, an organic layer OR1 and a cathode CE. The cathode CE opposes the anode AE1. The organic layer OR1 is located between the anode AE1 and the cathode CE.

The organic layer OR1 comprises a hole injection layer HIL, a hole transport layer HTL1, an electron blocking layer EBL, a light emitting layer B-EML, a hole blocking layer HBL, an electron transport layer ETL and an electron injection layer EIL. The light emitting layer B-EML is configured to emit blue light.

The hole injection layer HIL, the hole transport layer HTL1 and the electron blocking layer EBL are stacked one on another in this order and are located between the anode AE1 and the light emitting layer B-EML. The hole transport layer HTL1 has a thickness T1. The electron blocking layer EBL is in contact with the light emitting layer B-EML.

The hole blocking layer HBL, the electron transport layer ETL and the electron injection layer EIL are stacked one on another in this order and are located between the light emitting layer B-EML and the cathode CE. The hole blocking layer HBL is in contact with the light emitting layer B-EML.

In the example illustrated, a high refractive index layer HNL1 is located on the cathode CE, a low refractive index layer LNL is located on the high refractive index layer HNL1, and a sealing layer SEL is located on the low refractive index layer LNL. The high refractive index layer HNL1 has a thickness T11. The refractive index of the high refractive index layer HNL1 is greater than that of the low refractive index layer LNL. The stacked body of the high refractive index layer HNL1 and the low refractive index layer LNL serves as an optical adjustment layer (cap layer) that can improve the extraction efficiency of light emitted from the light emitting layer B-EML. The sealing layer SEL has the role of sealing the display element 201.

For example, the hole injection layer HIL, the hole transport layer HTL1, the electron blocking layer EBL, the hole blocking layer HBL, the electron transport layer ETL, the electron injection layer EIL, the cathode CE, the high refractive index layer HNL1, the low refractive index layer LNL and the sealing layer SEL are common layers disposed over the display elements 201, 202 and 203. The light emitting layer B-EML is an individual layer disposed in the display element 201.

The display element 202 comprises an anode AE2, an organic layer OR2 and a cathode CE. The anode AE2 is spaced apart from the anode AE1. The cathode CE opposes the anode AE2. The organic layer OR2 is located between the anode AE2 and the cathode CE.

The organic layer OR2 comprises a hole injection layer HIL, a hole transport layer HTL1, a hole transport layer HTL2, an electron blocking layer EBL, an light emitting layer G-EML, a hole blocking layer HBL, an electron transport layer ETL and an electron injection layer EIL. The light emitting layer G-EML is configured to emit green light. The light emitting layer G-EML is an individual layer disposed in the display element 202.

The hole injection layer HIL, the hole transport layer HTL1, the hole transport layer HTL2 and the electron blocking layer EBL are stacked one on another in this order and are located between the anode AE2 and the light emitting layer G-EML. The hole transport layers HTL1 and HTL2 are formed of the same material, for example, and together have a thickness T2. The thickness T2 is greater than the thickness T1. The electron blocking layer EBL is in contact with the light emitting layer G-EML.

The hole blocking layer HBL, the electron transport layer ETL and the electron injection layer EIL are stacked one on another in this order and are located between the light emitting layer G-EML and the cathode CE. The hole blocking layer HBL is in contact with the light emitting layer G-EML.

In the example illustrated, the high refractive index layer HNL1 is located on the cathode CE, the high refractive index layer HNL2 is located on the high refractive index layer HNL1, the low refractive index layer LNL is located on the high refractive index layer HNL2, and the sealing layer SEL is located on the low refractive index layer LNL. The high refractive index layers HNL1 and HNL2 are formed of the same material, for example and together have a thickness T12. The thickness T12 is greater than the thickness T11. The stacked body of the high refractive index layers HNL1 and HNL2 and the low refractive index layer LNL serves as an optical adjustment layer that can improve the extraction efficiency of light emitted from the light emitting layer G-EML. The sealing layer SEL has the role of sealing the display element 202.

The display element 203 comprises an anode AE3, an organic layer OR3 and a cathode CE. The anode AE3 is spaced apart from the anodes AE1 and AE2. The cathode CE opposes the anode AE3. The organic layer OR3 is located between the anode AE3 and the cathode CE.

The organic layer OR3 comprises a hole injection layer HIL, a hole transport layer HTL1, a hole transport layer HTL2, an electron blocking layer EBL, an light emitting layer R-EML, a hole blocking layer HBL, an electron transport layer ETL and an electron injection layer EIL. The light emitting layer R-EML is configured to emit red light.

The hole injection layer HIL, the hole transport layer HTL1, the hole transport layer HTL2 and the electron blocking layer EBL are stacked one on another in this order and are located between the anode AE3 and the light emitting layer R-EML. The hole transport layers HTL1 and HTL2 together have a thickness T3. For example, the thickness T3 is greater than thickness T2.

The hole blocking layer HBL, the electron transport layer ETL and the electron injection layer EIL are stacked one on another in this order and are located between the light emitting layer R-EML and the cathode CE.

In the example illustrated, the high refractive index layer HNL1 is located on the cathode CE, the high refractive index layer HNL2 is located on the high refractive index layer HNL1, the low refractive index layer LNL is located on the high refractive index layer HNL2, and the sealing layer SEL is located on the low refractive index layer LNL. The high refractive index layers HNL1 and HNL2 are formed of, for example, the same material and together have a thickness T13. For example, the thickness T13 is greater than the thickness T12. The stacked body of the high refractive index layers HNL1 and HNL2 and the low refractive index layer LNL serves as an optical adjustment layer that can improve the extraction efficiency of light emitted from the light emitting layer R-EML. The sealing layer SEL has the role of sealing the display element 203.

The hole injection layer HIL injects holes from the anodes AE1, AE2 and AE3 to the hole transport layer, and the hole transport layers HTL1 and HTL2 transport the injected holes to the light emitting layer EML. The electron blocking layer EBL keeps the electrons injected from the cathode CE in the light emitting layer EML and prevents electrons from leaking out to the hole transport layers HTL1 and HTL2.

The electron injection layer EIL injects electrons from the cathode CE to the electron transport layer ETL, and the electron transport layer ETL transports the injected electrons to the light emitting layer EML. The hole blocking layer HBL keeps holes injected from the anode in the light emitting layer EML and prevents holes from leaking out to the electron transport layer ETL.

As for the hole injection layer HIL and the hole transport layers HTL1 and HTL2, when the hole injection barrier (the difference between the work function of the anode and the HOMO level of the material of the hole transport layer) from the anodes AE1, AE2 and AE3 is reduced, holes are allowed to flow smoothly.

As for the electron injection layer EIL and the electron transport layer ETL, when the electron injection barrier (the difference between the work function of the cathode and the LUMO level of the material of the electron transport layer) from the cathode CE is reduced, electrons are allowed to flow smoothly.

The light emission in the organic layers OR1, OR2 and OR3 is obtained in the following mechanism. That is, when the excitation energy of excitons generated by holes injected to the highest occupied molecular orbital (HOMO, generally measured as ionization potential) of the material of the emitting layer EML and electrons injected to the lowest unoccupied molecular orbital (LUMO, generally measured as electron affinity) relaxes, light is emitted.

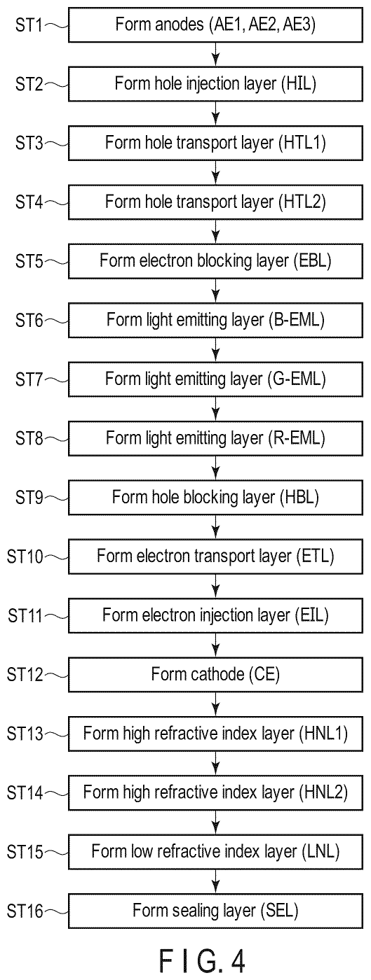

FIG. 4 is a diagram illustrating an example of a method of manufacturing the display elements 201, 202 and 203 shown in FIG. 3.

First, a conductive material is patterned to form the anodes AE1, AE2 and AE3 so as to be spaced apart from each other (step ST1). The anode AE1 is disposed in the pixel PXB, the anode AE2 is disposed in the pixel PXG and the anode AE3 is disposed in the pixel PXR. The anodes AE1, AE2 and AE3 are each a stacked body of, for example, a transparent electrode formed of indium tin oxide (ITO) or the like and a reflective electrode formed of silver (Ag) or the like.

After that, a rib is formed between each adjacent pair of the anodes AE1, AE2 and AE3. The rib may be an organic insulating film or an inorganic insulating film.

Next, a hole injection layer HIL is formed over the pixels PXB, PXG and PXR (step ST2). The hole injection layer HIL is disposed on the anodes AE1, AE2 and AE3.

Then, a hole transport layer HTL1 is formed over the pixels PXB, PXG and PXR (step ST3). The hole transport layer HTL1 is disposed on the hole injection layer HIL.

Subsequently, a hole transport layer HTL2 is formed in the pixels PXG and PXR (step ST4). The hole transport layer HTL2 is disposed on the hole transport layer HTL1 in each of the pixels PXG and PXR. At this time, as shown in FIG. 3, the hole transport layer HTL2 in the pixel PXR is formed to be thicker than the hole transport layer HTL2 in the pixel PXG.

Next, an electron blocking layer EBL is formed over the pixels PXB, PXG and PXR (step ST5). The electron blocking layer EBL is disposed on the hole transport layer HTL1 in the pixel PXB and also on the hole transport layer HTL2 in each of the pixels PXG and PXR.

Then, in the pixel PXB, a light emitting layer B-EML is formed (step ST6). The light emitting layer B-EML is formed by co-evaporation of a host material and a dopant that emits blue light. The light emitting layer B-EML is disposed on the electron blocking layer EBL and directly above the anode AE1.

Subsequently, in the pixel PXG, a light emitting layer G-EML is formed (step ST7). The light emitting layer G-EML is formed by co-evaporation of a host material and a dopant that emits green light. The light emitting layer G-EML is disposed on the electron blocking layer EBL and directly above the anode AE2.

Next, in the pixel PXR, a light emitting layer R-EML is formed (step ST8). The light emitting layer R-EML is formed by co-deposition of a host material and a dopant that emits red light. The light emitting layer R-EML is disposed on the electron blocking layer EBL and directly above the anode AE3.

Note that the order of formation of the light emitting layers B-EML, G-EML and R-EML is not limited to that of the example shown in FIG. 4. The chromaticity of red is: CIEx=0.635 and CIEy=0.315, that of green is: CIEx=0.227 and CIEy=0.717, and that of blue is CIEx=0.141 and CIEy=0.05. CIEx for red, CIEy for green and CIEy for blue serve an important role in the pixel design.

Next, a hole blocking layer HBL is formed over the pixels PXB, PXG and PXR (step ST9). The hole blocking layer HBL is disposed on the light emitting layer B-EML in the pixel PXB, on the light emitting layer G-EML in the pixel PXG, and on the light emitting layer R-EML in the pixel PXR.

Then, an electron transport layer ETL is formed over the pixels PXB, PXG and PXR (step ST10). The electron transport layer ETL is disposed on the hole blocking layer HBL.

Subsequently, an electron injection layer EIL is formed over the pixels PXB, PXG and PXR (step ST11). The electron injection layer EIL is disposed on the electron transport layer ETL.

After that, a cathode CE is formed over the pixels PXB, PXG and PXR (step ST12). The cathode CE is disposed on the electron injection layer EIL. The cathode CE is formed, for example, of an alloy of magnesium (Mg) and silver (Ag).

Next, a high refractive index layer HNL1 is formed over the pixels PXB, PXG and PXR (step ST13). The high refractive index layer HNL1 is disposed on the cathode CE.

Then, a high refractive index layer HNL2 is formed over the pixels PXG and PXR (step ST14). The high refractive index layer HNL2 is disposed on the high refractive index layer HNL1 in each of the pixels PXG and PXR. At this time, as shown in FIG. 3, the high refractive index layer HNL2 in the pixel PXR is formed to be thicker than the high refractive index layer HNL2 in the pixel PXG.

Subsequently, a low refractive index layer LNL is formed over the pixels PXB, PXG and PXR (step ST15). The low refractive index layer LNL is disposed on the high refractive index layer HNL1 in the pixel PXB and also on the high refractive index layer HNL2 in each of the pixels PXG and PXR.

After that, a sealing layer SEL is formed over the pixels PXB, PXG and PXR (step ST16). The sealing layer SEL is disposed on the low refractive index layer LNL.

It should be noted here that in the above-described manufacturing process, the light emitting layer B-EML is formed at a deposition rate of 0.12 nm per second or higher, and more preferably at a deposition rate of 0.17 nm per second or higher.

Further, the other light emitting layers G-EML and R-EML may as well be formed at a deposition rate of 0.12 nm per second or higher, and preferably at a deposition rate of 0.17 nm per second or higher.

Furthermore, the hole transport layers HTL1 and HTL2, which are the underlying layers of the light emitting layers B-EML, G-EML and R-EML, may as well be formed at a deposition rate of 0.12 nm per second or higher, or at a deposition rate of 0.17 nm per second or higher.

The inventors conducted an experiment in which light emitting layers B-EML were formed under different conditions in terms of deposition rate and compared the light emission properties thereof with each other.

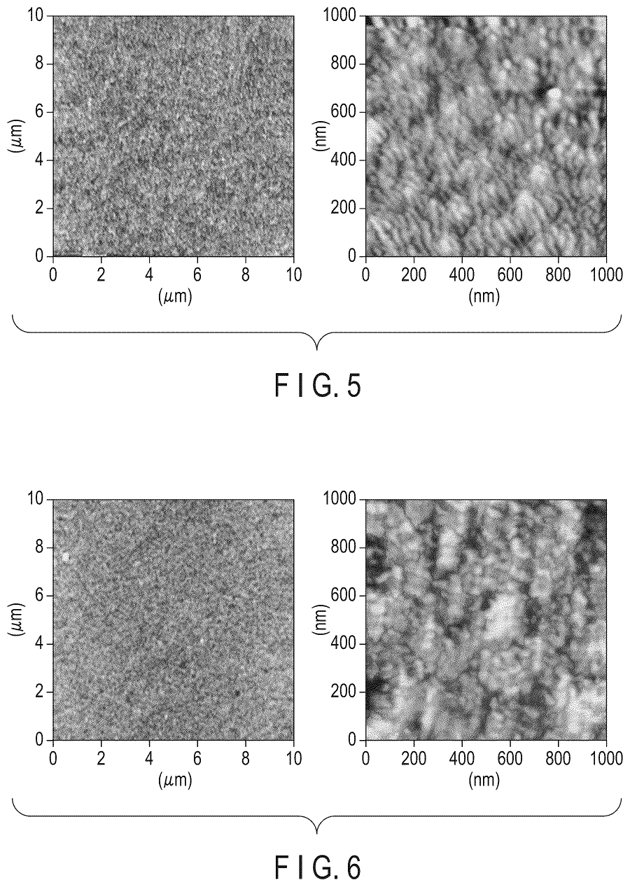

FIG. 5 is a diagram including micrographs each showing the light emitting layer B-EML formed at respective deposition rates of an embodiment.

In this embodiment, the hole injection layer HIL was formed at a deposition rate of 0.04 nm per second, the hole transport layer HTL1 was formed at a deposition rate of 0.17 nm per second, the electron blocking layer EBL was formed at a deposition rate of 0.04 nm per second, and the light emitting layer B-EML was formed at a deposition rate of 0.17 nm per second.

In the diagram, the photo on the left side shows a square area with a side of 10 μm(, which will be referred to as an area A1, hereinafter), and the photo on the right side shows a square area with a side of 1 μm. In the area A1, the average particle size per unit area was 39 nm. Further, according to the analysis of the cross-section of the light emitting layer B-EML, the average value of step differences taken between each adjacent pair of projections and recesses was 2.2 nm.

FIG. 6 is a diagram including micrographs each showing a light emitting layer B-EML formed at respective deposition rates in a comparative example.

In the comparative example, the hole injection layer HIL was formed at a deposition rate of 0.04 nm per second, the hole transport layer HTL1 was formed at a deposition rate of 0.04 nm per second, the electron blocking layer EBL was formed at a deposition rate of 0.04 nm per second, and the light emitting layer B-EML was formed at a deposition rate of 0.04 nm per second.

In the diagram, the photo on the left side shows a square area with a side of 10 μm(, which will be referred to as an area A1, hereinafter), and the photo on the right side shows a square area with a side of 1 μm. In the area A1, the average particle size per unit area was 96.2 nm. Further, according to the analysis of the cross-section of the light emitting layer B-EML, the average value of step differences taken between each adjacent pair of projections and recesses was 3.3 nm.

As comparing the results shown in FIGS. 5 and 6, it was confirmed that by increasing the deposition rates of the hole transport layer HTL1 and the light emitting layer B-EML four times or more those of the comparative example, the average particle size of the material (host material) which forms the light emitting layer B-EML can be reduced to ½ or less and the particle distribution can be made uniform.

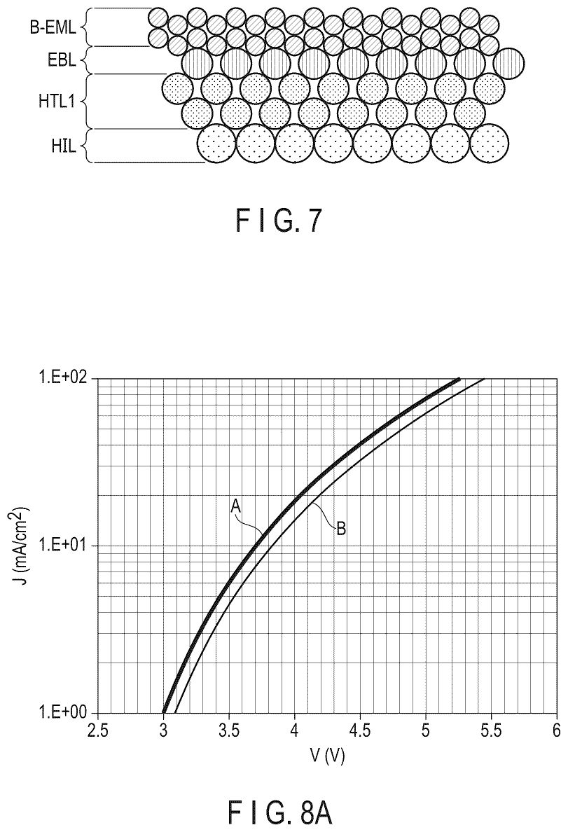

FIG. 7 is a diagram showing a modelled configuration of each layer of the organic layer OR1.

Here, the hole injection layer HIL, the hole transport layer HTL1, the electron blocking layer EBL, and the light emitting layer B-EML in the organic layer

OR1 are shown.

The layers located lower than the light emitting layer B-EML are formed to have a relatively large particle diameter. The light emitting layer B-EML is formed to have a relatively small particle diameter so as to fill the steps in the lower layer. Thus, the average particle diameter of the material which constitutes the light emitting layer B-EML is smaller than that of the material which constitutes the hole transport layer HTL1.

Note that in the case where the light emitting layers G-EML and R-EML are formed at a deposition rate similar to that of the light emitting layer B-EML, a model similar to that shown in FIG. 7 is realized. That is, the average particle diameter of the material which constitutes the light emitting layers G-EML and R-EML is smaller than that of the material which constitutes the hole transport layers HTL1 and HTL2.

Next, effects of making fine particle size (an average particle diameter of 39 nm or less) of the material which constitutes the light emitting layer B-EML will be described.

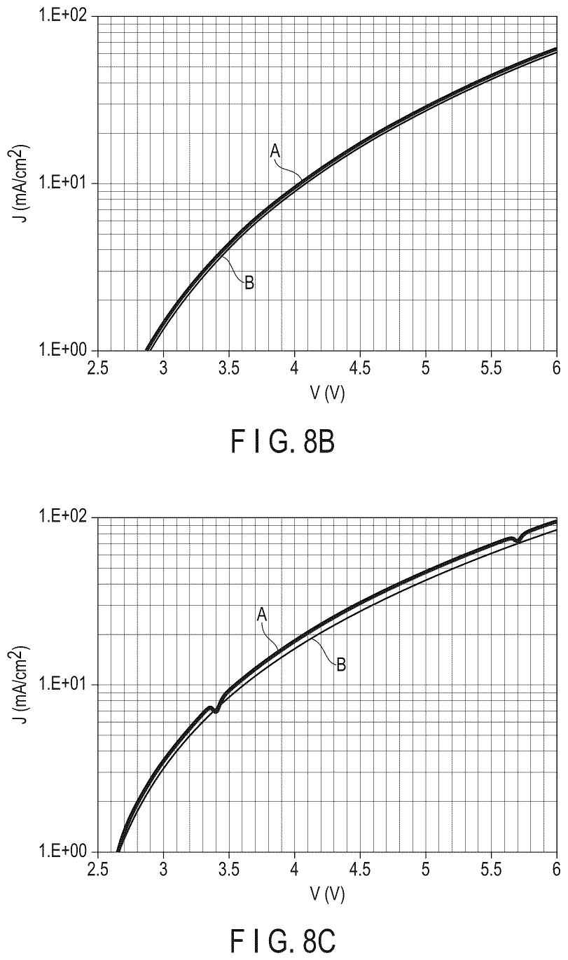

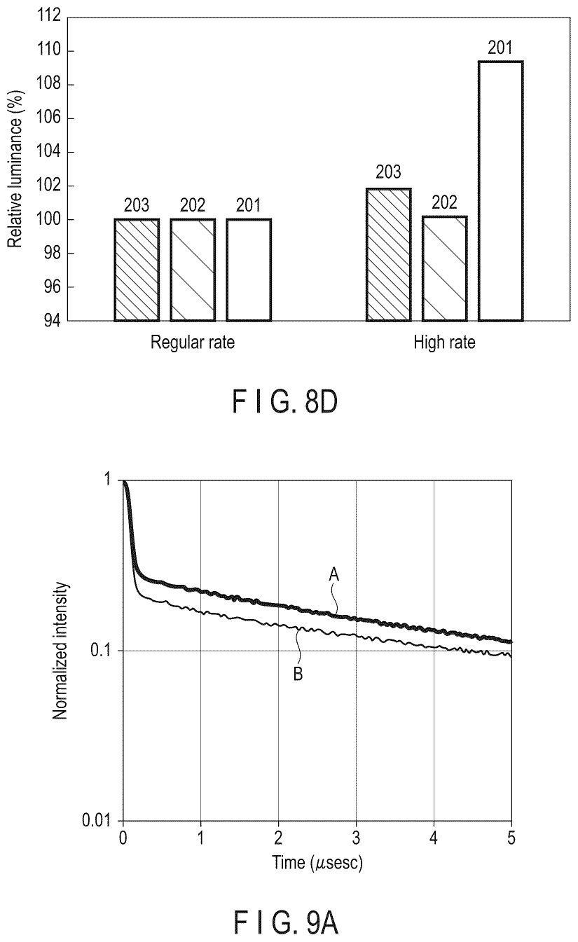

FIG. 8A is a diagram illustrating an example of the relationship between applied voltage and current density in the display element 201.

In the figure, the horizontal axis indicates the applied voltage (V), whereas the vertical axis indicates the current density (mA/cm²).

A curve A in the figure shows the results of the embodiment in which the hole transport layer HTL1 and the light emitting layer B-EML were formed at a deposition rate of 0.17 nm per second.

A curve B in the figure shows the results of a comparative example in which the hole transport layer HTL1 and the light emitting layer B-EML were formed at a deposition rate of 0.04 nm per second.

As shown in FIG. 8A, it has been confirmed that according to the embodiment, a higher current density can be obtained at the same applied voltage. In other words, according to the embodiment, it has been confirmed that the applied voltage required to obtain the same current density can be reduced.

Further, the effects have been confirmed for the light emitting layer G-EML and the light emitting layer R-EML as well formed at the deposition rate described above.

FIG. 8B is a diagram illustrating an example of the relationship between applied voltage and current density in the display element 202.

A curve A in the figure shows the characteristics of the embodiment in which the hole transport layer HTL1 and the light emitting layer G-EML were formed at a deposition rate of 0.17 nm per second.

A curve B in the figure shows the characteristics of the comparative example in which the hole transport layer HTL1 and the light emitting layer G-EML were formed at a deposition rate of 0.04 nm per second.

FIG. 8C is a diagram illustrating an example of the relationship between applied voltage and current density in the display element 203.

A curve A in the figure shows the characteristics of the embodiment in which the hole transport layer HTL1 and the light emitting layer R-EML are formed at a deposition rate of 0.17 nm per second.

A curve B in the figure shows the characteristics of the comparative example in which the hole transport layer HTL1 and the light emitting layer R-EML were formed at a deposition rate of 0.04 nm per second.

According to the embodiments of the light emitting layer G-EML in the display element 202 and the light emitting layer R-EML in the display element 203, the effect on the applied voltage is negligibly small when compared to the light emitting layer B-EML, or the effect of reducing the applied voltage required to obtain the same current density is slight. As comparing the light emitting layer B-EML, the light emitting layer G-EML and the light emitting layer R-EML with each other, it has been confirmed that the effect is greatest in the light emitting layer B-EML.

FIG. 8D is a diagram showing the efficiency in the display elements 201, 202 and 203.

According to the model of the organic layer OR1 illustrated in FIG. 7, a uniform effect is not obtained for all the light emitting layers R-EML, G-EML and B-EML, but only for the light emitting layer B-EML, a higher intensity relative luminance can be obtained.

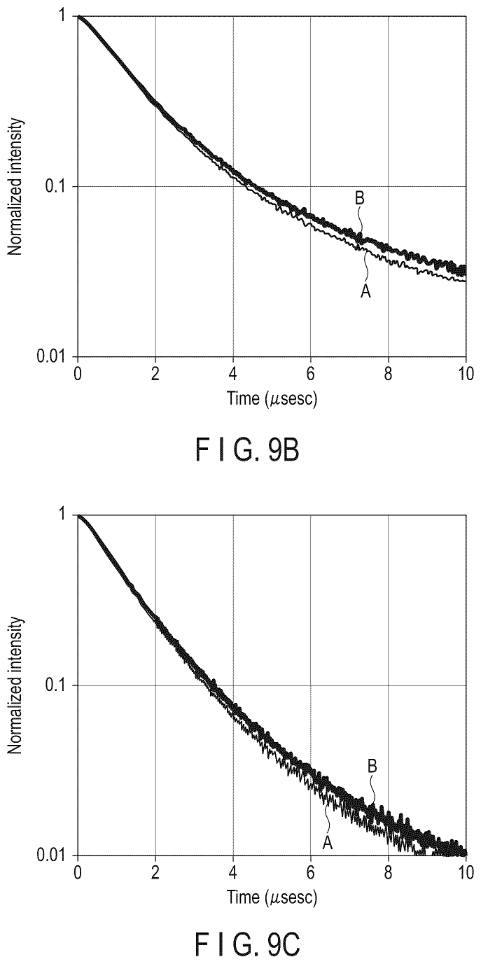

FIG. 9A is a diagram showing the decay process of the luminescence intensity over elapsed time in the display element 201.

In the figure, the horizontal axis indicates the elapsed time (μsec) from power off, whereas the vertical axis indicates the relative intensity. The relative intensity is represented as a relative value when the intensity at the elapsed time of 0 seconds is set to 1.

A curve A in the figure shows the characteristics of the embodiment in which the hole transport layer HTL1 and the light emitting layer B-EML were formed at a deposition rate of 0.17 nm per second.

A curve B in the figure shows the characteristics of the comparative example in which the hole transport layer HTL1 and the light emitting layer B-EML were formed at a deposition rate of 0.04 nm per second.

As shown in FIG. 9A, it has been confirmed that according to the embodiment, a higher intensity than that of the comparative case can be provided in delayed fluorescence. Fluorescent molecules of such as blue color are known to be able to obtain a higher intensity with an increase in up-conversion. That is, it is presumed that due to the micro-particulation of the material which constitutes the light emitting layer B-EML, the current density per single molecule is enhanced to increase the up-conversion. According to the embodiment, the efficiency is improved by about 10% in the light emitting layer B-EML of the display element 201.

FIG. 9B is a diagram showing the decay process of luminescence intensity over elapsed time in the display element 202.

The horizontal axis of the figure indicates the elapsed time (μsec) from power off, and the vertical axis of the figure indicates the relative intensity. The relative intensity is represented as a relative value when the intensity at the elapsed time of 0 seconds is set to 1.

A curve A in the figure shows the characteristics of the embodiment in which the hole transport layer HTL1 and the light emitting layer G-EML were formed at a deposition rate of 0.17 nm per second.

A curve B in the figure shows the characteristics of the comparative example in which the hole transport layer HTL1 and the light emitting layer G-EML were formed at a deposition rate of 0.04 nm per second.

As shown in FIG. 9B, it has been confirmed that according to the embodiment, a lower intensity than that of the comparative case can be provided in delayed fluorescence. It is known that the intensity of phosphorescent molecules of such as green and red colors decreases with an increase in up-conversion. That is, it is presumed that due to the micro-particulation of the material which constitutes the light emitting layer G-EML, the current density per single molecule is increased, resulting in an increase in up-conversion. However, in this embodiment, the effect of the light emitting layer G-EML of the display element 202 is negligibly small even though the efficiency may decrease.

FIG. 9C is a diagram showing the decay process of luminescence intensity in the display element 203 over elapsed time.

The horizontal axis of the figure indicates the elapsed time (μsec) from power off, and the vertical axis of the figure indicates the relative intensity. The relative intensity is represented as a relative value when the intensity at an elapsed time of 0 seconds is set to 1.

A curve A in the figure shows the characteristics of the embodiment in which the hole transport layer HTL1 and the light emitting layer R-EML were formed at a deposition rate of 0.17 nm per second.

A curve B in the figure shows the characteristics of the comparative example in which the hole transport layer HTL1 and the light emitting layer R-EML were formed at a deposition rate of 0.04 nm per second.

As shown in FIG. 9C, it has been confirmed that according to the embodiment, a lower intensity than that of the comparative case can be obtained in delayed fluorescence. It is known that the intensity of phosphorescent molecules such as of green and red colors decreases along with an increase in up-conversion. That is, it is presumed that the micro-particulation of the material which constitutes the light emitting layer R-EML increased the current density per single molecule, resulting in an increase in up-conversion. However, in the embodiment, the effect of the light emitting layer R-EML of the display element 203 is negligibly small even though the efficiency may decrease.

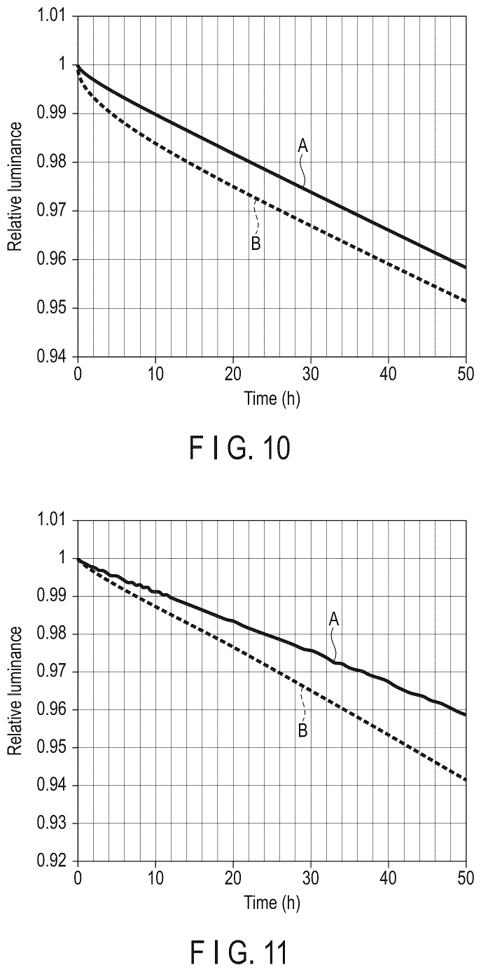

FIG. 10 is a diagram showing the change in luminous intensity in the display element 201 over elapsed time. The results shown here correspond to the change over elapsed time in luminance obtained when a constant current is continuously applied to the display element 201.

The horizontal axis of the figure indicates the elapsed time, whereas the vertical axis of the figure indicates the relative luminance. The relative luminance is represented as a relative value when the luminance at an elapsed time of 0 hours is set to 1.

A curve A in the figure shows the results of the embodiment in which the hole transport layer HTL1 and the light emitting layer B-EML were formed at a deposition rate of 0.17 nm per second.

A curve B in the figure shows the result of the comparative example in which the hole transport layer HTL1 and the light emitting layer B-EML were formed at a deposition rate of 0.04 nm per second.

As shown in FIG. 10, it has been confirmed that, according to the embodiment, though the luminance decreases along with time, a higher luminance than that of the comparative case can be obtained at any time. That is, it has been confirmed that according to the embodiment, a longer life than that of the comparative example can be achieved. It is presumed that the micro-particulation of the material which constitutes the light emitting layer B-EML allows the current to flow uniformly in the light emitting layer B-EML.

As explained above, according to this embodiment, due to the micro-particulation of the material which constitutes the light emitting layer B-EML, the light emission characteristics in the display element 201 can be improved. In particular, when the average particle diameter per unit area of the material constituting the light emitting layer B-EML is 39 nm or less, the improvement in light emission characteristics is particularly noticeable. Such a light emitting layer B-EML can be obtained by forming it at a deposition rate of 0.12 nm per second or higher, more preferably 0.17 nm per second or higher.

Next, the display elements 202 and 203 will be discussed.

FIG. 11 is a diagram showing the change in luminescence in light emission over elapsed time in the display element 202. The results shown here correspond to the change over time in luminance obtained when a constant voltage is continuously applied to the display element 202.

The horizontal axis of the figure indicates the elapsed time, whereas the vertical axis of the figure indicates the relative luminance. The relative luminance is represented as a relative value when the luminance at an elapsed time of 0 hours is set to 1.

A curve A in the figure shows the results of the embodiment in which the hole transport layers HTL1 and HTL2 and the light emitting layer G-EML were formed at a deposition rate of 0.17 nm per second.

A curve B in the figure shows the results of the comparative example in which the hole transport layers HTL1 and HTL2 and the light emitting layer G-EML were formed at a deposition rate of 0.04 nm per second.

As shown in FIG. 11, it has been confirmed that, according to the embodiment, though the luminance decreased over time in the display device 202, a higher luminance than that of the comparative example can be obtained at any time. That is, it has been confirmed that the display element 202 of the embodiment can achieve a longer life than that of the comparative example.

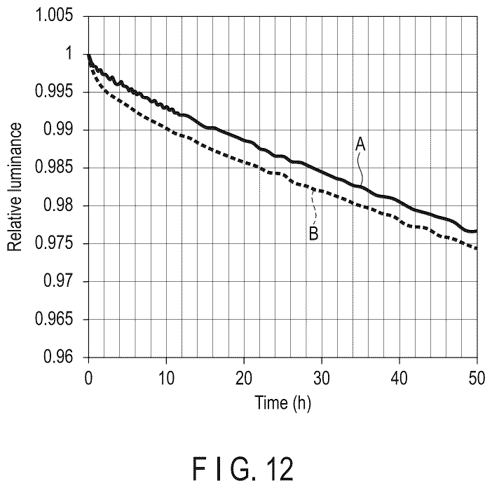

FIG. 12 is a diagram showing the change in luminance in light emission in the display element 203 over time. The results shown here correspond to the change over time in luminance obtained when a constant voltage is continuously applied to the display element 203.

The horizontal axis of the figure indicates the elapsed time, whereas the vertical axis of the figure indicates the relative luminance. The relative luminance is represented as a relative value when the luminance at an elapsed time of 0 hours is set to 1.

A curve A in the figure shows the results of the embodiment in which the hole transport layers HTL1 and HTL2 and the light emitting layer R-EML were formed at a deposition rate of 0.17 nm per second.

A curve B in the figure shows the results of a comparative example in which the hole transport layers HTL1 and HTL2 and light emitting layer R-EML were formed at a deposition rate of 0.04 nm per second.

As shown in FIG. 12, it has been confirmed that, according to the embodiment, though the luminance decreased over time in the display element 203, a higher luminance than that of the comparative example can be obtained at any time. That is, it has been confirmed that the display element 203 of the embodiment can achieve a longer life than that of the comparative example.

As described above, in the display elements 202 and 203 as well, due to the micro-particulation of the material that constitutes the light emitting layer, the light emission characteristics can be improved. Such light emitting layers G-EML and R-EML can be obtained by forming at a deposition rate of 0.12 nm per second or higher, more preferably 0.17 nm per second or higher.

In this embodiment, for example, the anode AE1 corresponds to the first anode, the organic layer OR1 corresponds to the first organic layer, the light emitting layer B-EML corresponds to the first light emitting layer, the anode AE2 corresponds to the second anode, the organic layer OR2 corresponds to the second organic layer, the light emitting layer G-EML corresponds to the second light emitting layer, the anode AE3 corresponds to the third anode, the organic layer OR3 corresponds to the third organic layer, and the emitting layer R-EML corresponds to the third emitting layer. Alternatively, the light emitting layer B-EML containing fluorescent molecules which emit blue fluorescence, the light emitting layer G-EML containing phosphorescent molecules which emit green phosphorescence, or the light emitting layer R-EML containing phosphorescent molecules which emit red phosphorescence may correspond to the first light emitting layer.

As explained above, according to this embodiment, it is possible to provide a display device with improved light emission characteristics and a method of manufacturing such a display device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a first anode;
a cathode opposing the first anode; and
a first organic layer located between the first anode and the cathode, wherein
the first organic layer includes a first light emitting layer and a hole transport layer located between the first anode and the first light emitting layer, and
an average particle diameter per unit area of a material which constitutes the first light emitting layer is smaller than an average particle diameter per unit area of a material which constitutes the hole transport layer.

2. The display device of claim 1, wherein
the average particle diameter per unit area of the material which constitutes the first light emitting layer is 39 nm or less.

3. The display device of claim 1, wherein
at least one of the hole transport layer and the first light emitting layer is formed at a deposition rate of 0.12 nm per second or higher.

4. The display device of claim 1, wherein
at least one of the hole transport layer and the first light emitting layer is formed at a deposition rate of 0.17 nm per second or higher.

5. The display device of claim 1, further comprising:
a second anode spaced apart from the first anode;
a third anode spaced apart from the first anode and the second anode;
a second organic layer located between the second anode and the cathode and including a second light emitting layer formed of a material different from that of the first light emitting layer; and
a third organic layer located between the third anode and the cathode and including a third light emitting layer formed of a material different from those of the first light emitting layer and the second light emitting layer,
wherein
the second light emitting layer and the third light emitting layer are formed at a deposition rate of 0.12 nm per second or higher.

6. The display device of claim 5, wherein
the second light emitting layer and the third light emitting layer are formed at a deposition rate of 0.17 nm per second or higher.

7. The display device of claim 1, wherein
the first light emitting layer contains fluorescent molecules which emit blue fluorescence.

8. The display device of claim 1, wherein
the first light emitting layer contains phosphorescent molecules which emit green phosphorescence.

9. The display device of claim 1, wherein
the first light emitting layer contains phosphorescent molecules which emit red phosphorescence.

10. A method of manufacturing a display device, comprising:
forming a first anode;
forming a first organic layer on the first anode; and
forming a cathode on the first organic layer, wherein
the forming the first organic layer comprises:
forming a hole transport layer; and
forming a first light emitting layer,
the hole transport layer is located between the first anode and the first light emitting layer, and
at least one of the hole transport layer and the first light emitting layer is formed at a deposition rate of 0.12 nm per second or higher.

11. The method of claim 10, wherein
at least one of the hole transport layer and the first light emitting layer is formed at a deposition rate of 0.17 nm per second or higher.

12. The method of claim 10, further comprising:
forming, when forming the first anode, a second anode spaced apart from the first anode and a third anode spaced apart from the first anode and the second anode, simultaneously;
forming a second organic layer on the second anode before forming the cathode; and
forming a third organic layer on the third anode before forming the cathode, wherein
the forming the second organic layer comprises forming a second light emitting layer,
the forming the third organic layer comprises forming a third light emitting layer, and
the second light emitting layer and the third light emitting layer are formed at a deposition rate of 0.12 nm per second or higher.

13. The method of claim 12, wherein
the second light emitting layer and the third light emitting layer are formed at a deposition rate of 0.17 nm per second or higher.

14. The method of claim 10, wherein
the first light emitting layer contains fluorescent molecules which emit blue fluorescence.

15. The method of claim 10, wherein
the first light emitting layer contains phosphorescent molecules which emit green phosphorescence.

16. The method of claim 10, wherein
the first light emitting layer contains phosphorescent molecules which emit red phosphorescence.
